(19) United States
(12) Patent Application Publication
(10) Pub. No.: US 2025/0304818 A1
(43) Pub. Date: Oct. 2, 2025

(54) POLYMER COMPOSITION, POLYMER FILM PRECURSOR, POLYMER FILM, LAMINATE PRECURSOR, AND LAMINATE

(71) Applicant: FUJIFILM Corporation, Tokyo (JP)

(72) Inventors: Yasuyuki SASADA, Kanagawa (JP); Satoshi KUNIYASU, Kanagawa (JP)

(73) Assignee: FUJIFILM Corporation, Tokyo (JP)

(21) Appl. No.: 19/236,896

(22) Filed: Jun. 12, 2025

Related U.S. Application Data
(63) Continuation of application No. PCT/JP2023/040949, filed on Nov. 14, 2023.

(30) Foreign Application Priority Data
Dec. 16, 2022 (JP) 2022-201482

(51) Int. Cl. C09D 177/12; C09D 153/02; H05K 1/03

(52) U.S. Cl. CPC C09D 177/12; C09D 153/02; H05K 1/032; H05K 2201/0141; H05K 2201/015

(57) ABSTRACT

A polymer composition including particles having a ratio of an average particle diameter D90 to an average particle diameter D50 of 2.3 or less, and a polymer having a dielectric loss tangent of 0.01 or less, and applications thereof.

### CROSS-REFERENCE TO RELATED APPLICATIONS

This application is a continuation application of International Application No. PCT/JP2023/040949, filed Nov. 14, 2023, the disclosure of which is incorporated herein by reference in its entirety. Further, this application claims priority from Japanese Patent Application No. 2022-201482, filed Dec. 16, 2022, the disclosure of which is incorporated herein by reference in its entirety.

### BACKGROUND OF THE INVENTION

### 1. Field of the Invention

The present disclosure relates to a polymer composition, a polymer film precursor, a polymer film, a laminate precursor, and a laminate.

### 2. Description of the Related Art

In recent years, frequencies used in a communication equipment tend to be extremely high. In order to suppress transmission loss in a high frequency band, insulating materials used in a circuit board are required to have a lowered relative permittivity and a lowered dielectric loss tangent. A copper-clad laminated plate is suitably used as a member constituting a circuit board, and a polymer film is suitably used for producing the copper-clad laminated plate.

For example, JP2019-199612A discloses a resin composition including a styrene-based polymer, an inorganic filler, and a curing agent, in which the styrene-based polymer is an acid-modified styrene-based polymer having a carboxyl group, the inorganic filler is silica and/or aluminum hydroxide, a particle diameter of the inorganic filler is 1 μm or less, a content of the inorganic filler is 20 to 80 parts by mass with respect to 100 parts by mass of the styrene-based polymer, and the resin composition satisfies Expressions (A) and (B) in a form of a film having a thickness of 25 μm.

JP2022-17947A describes a thermosetting adhesive sheet including a binder resin and a curing agent, in which a cured product obtained by heating a thermosetting adhesive sheet at 180° C. for 1 hour satisfies (i) to (iv).
(i) In a case where the thickness of the cured product is 25 μm, the energy ray transmittance at a wavelength of 355 nm is 0% to 40%.
(ii) The relative permittivity is 1.5 to 3.0 at a frequency of 10 GHz and at 23° C.
(iii) The dielectric loss tangent is 0.0001 to 0.01 at a frequency of 10 GHz and at 23° C.
(iv) The linear expansion coefficient al at 0° C. to the glass transition temperature is 100 to 500 ppm/° C.

### SUMMARY OF THE INVENTION

Typically, a copper-clad laminated plate is produced by laminating a copper foil on a surface of a polymer film. In addition, the wiring board is produced by superimposing a copper-clad laminated plate and a wiring substrate such that a polymer film in the copper-clad laminated plate and the wiring substrate are in contact with each other. In a case of producing a wiring board, from the viewpoint of adhesiveness, it is required that the polymer film deforms by following the step formed on the surface of the wiring substrate.

In recent years, wiring patterns have become more detailed, and thus it is required to follow and deform in response to a more detailed step than before.

An object to be achieved by an embodiment of the present invention is to provide a polymer composition suitable for producing a polymer film having excellent step followability in a case of being bonded to a wiring line.

An object to be achieved by another embodiment of the present invention is to provide a polymer film precursor, a polymer film, a laminate precursor, and a laminate, which have excellent step followability in a case of being bonded to a wiring line.

The means for achieving the above-described objects include the following aspects.

<1>

A polymer composition including:
particles having a ratio of an average particle diameter D90 to an average particle diameter D50 of 2.3 or less; and
a polymer having a dielectric loss tangent of 0.01 or less.
   <2>

The polymer composition according to <1>, in which the average particle diameter D90 is 20 μm or less.

<3>

The polymer composition according to <1> or <2>, in which a content of the particles is 40% by mass or more and less than 100% by mass with respect to a total amount of the polymer composition.

<4>

The polymer composition according to any one of <1> to <3>, in which the particles have an elastic modulus at 160° C. of 10 MPa or less.

<5>

The polymer composition according to any one of <1> to <4>, in which the particles contain an organic substance as a main component.

<6>

The polymer composition according to any one of <1> to <5>, in which the particles contain a thermoplastic elastomer.

<7>

The polymer composition according to any one of <1> to <6>, in which the polymer having a dielectric loss tangent of 0.01 or less has a mass residual rate at 440° C. of 80% or more.

<8>

The polymer composition according to any one of <1> to <7>, in which the polymer having a dielectric loss tangent of 0.01 or less contains an aromatic polyester amide.

<9>

A polymer film precursor including:
particles having a ratio of an average particle diameter D90 to an average particle diameter D50 of 2.3 or less; and
a polymer having a dielectric loss tangent of 0.01 or less.
   <10>

The polymer film precursor according to <9>, in which the average particle diameter D90 is 20 μm or less.

<11>

The polymer film precursor according to <9> or <10>, in which a content of the particles is 40% by mass or more and less than 100% by mass with respect to a total amount of the polymer film precursor.

<12>

The polymer film precursor according to any one of <9> to <11>, in which wherein the particles have an elastic modulus at 160° C. of 10 MPa or less.

<13>

The polymer film precursor according to any one of <9> to <12>, in which the particles contain a thermoplastic elastomer.

<14>

The polymer film precursor according to any one of <9> to <13>, in which the polymer having a dielectric loss tangent of 0.01 or less has a mass residual rate at 440° C. of 80% or more.

<15>

The polymer film precursor according to any one of <9> to <14>, in which the polymer having a dielectric loss tangent of 0.01 or less contains an aromatic polyester amide.

<16>

A polymer film including a phase-separated structure including at least two phases, in which a distribution width of an elastic modulus at 160° C. is less than 100 MPa.

<17>

The polymer film according to <16>, in which the polymer film has a mass residual rate at 440° C. of 20% or more.

<18>

The polymer film according to <16> or <17>, in which the polymer film has a viscosity at 260° C. of 1,000 Pa·s or more.

<19>

A laminate precursor including:
a layer A; and
a layer B disposed on at least one surface of the layer A,
in which the layer B contains particles having a ratio of an average particle diameter D90 to an average particle diameter D50 of 2.3 or less, and a polymer having a dielectric loss tangent of 0.01 or less.
   <20>

A laminate including:
a layer A; and
a layer B disposed on at least one surface of the layer A,
in which the layer B has a phase-separated structure including at least two phases, and a distribution width of an elastic modulus at 160° C. of less than 100 MPa.

According to an embodiment of the present invention, there is provided a polymer composition suitable for producing a polymer film having excellent step followability in a case of being bonded to a wiring line.

According to another embodiment of the present invention, there are provided a polymer film precursor, a polymer film, a laminate precursor, and a laminate, which have excellent step followability in a case of being bonded to a wiring line.

### DESCRIPTION OF THE PREFERRED EMBODIMENTS

Hereinafter, the contents of the present disclosure will be described in detail. The description of configuration requirements below is made based on representative embodiments of the present disclosure in some cases, but the present disclosure is not limited to such embodiments.

In the present specification, a numerical range shown using “to” indicates a range including numerical values described before and after “to” as a lower limit value and an upper limit value.

In a numerical range described in a stepwise manner in the present disclosure, an upper limit value or a lower limit value described in one numerical range may be replaced with an upper limit value or a lower limit value in another numerical range described in a stepwise manner. In addition, in a numerical range described in the present disclosure, an upper limit value or a lower limit value described in the numerical range may be replaced with a value described in an example.

In addition, in a case where substitution or unsubstitution is not noted in regard to the notation of a “group” (atomic group) in the present specification, the “group” includes not only a group that does not have a substituent but also a group having a substituent. For example, the concept of an “alkyl group” includes not only an alkyl group that does not have a substituent (unsubstituted alkyl group) but also an alkyl group having a substituent (substituted alkyl group).

In the present specification, the concept of “(meth)acryl” includes both acryl and methacryl, and the concept of “(meth)acryloyl” includes both acryloyl and methacryloyl.

Further, the term “step” in the present specification indicates not only an independent step but also a step which cannot be clearly distinguished from other steps as long as the intended purpose of the step is achieved.

Furthermore, in the present disclosure, a combination of two or more preferred embodiments is a more preferred embodiment.

In addition, the weight-average molecular weight (Mw) and the number-average molecular weight (Mn) in the present disclosure are molecular weights converted using polystyrene as a standard substance by performing detection with a gel permeation chromatography (GPC) analysis apparatus using TSKgel SuperHM-H (trade name, manufactured by Tosoh Corporation) column, a solvent of pentafluorophenol (PFP) and chloroform at a mass ratio of 1:2, and a differential refractometer, unless otherwise specified.

### [Polymer Composition]

The polymer composition according to the present disclosure contains particles in which a ratio of an average particle diameter D90 to an average particle diameter D50 (that is, “average particle diameter D90/average particle diameter D50”) is 2.3 or less, and a polymer having a dielectric loss tangent of 0.01 or less.

The average particle diameter D50 indicates an average particle diameter of particles in a case where the number of particles is 50% by volume in a population of particles to be measured.

The average particle diameter D90 indicates an average particle diameter of particles in a case where the number of particles is 90% by volume in a population of particles to be measured.

In the particles, the ratio of the average particle diameter D90 to the average particle diameter D50 being 2.3 or less means that the particle size distribution is narrow.

As a result of intensive studies, the present inventors have found that, by adopting the above-described configuration, it is possible to provide a polymer composition suitable for a polymer film having excellent step followability in a case of being bonded to a wiring line.

The detailed mechanism that brings about the aforementioned effect is unclear, but is assumed to be as below.

In a case where the particle size distribution of the particles contained in the polymer composition is narrow, the distribution width of the elastic modulus in the polymer film is small in a case where the polymer composition is used to form a polymer film. In particular, it is considered that, in a case of carrying out the laminated press working, it is possible to suppress a local decrease in surface pressure, and the step followability is excellent.

On the other hand, JP2019-199612A and JP2022-17947A do not describe a combination of the ratio of the average particle diameter D90 to the average particle diameter D50 and the polymer having a dielectric loss tangent of 0.01 or less.

### (Particles)

The polymer composition according to the present disclosure includes particles (hereinafter, also referred to as “specific particles”) having a ratio of an average particle diameter D90 to an average particle diameter D50 of 2.3 or less.

From the viewpoint of further improving the step followability, a ratio of the average particle diameter D90 to the average particle diameter D50 is preferably more than 1.0 and 2.3 or less, more preferably more than 1.0 and 2.0 or less, and still more preferably more than 1.0 and 1.8 or less.

The average particle diameter D50 is preferably 0.1 μm to 20 μm and more preferably 1 m to 10 μm.

The average particle diameter D90 is preferably 20 μm or less and more preferably 1 m to 15 μm.

The average particle diameter D50 and the average particle diameter D90 are measured using a laser diffraction/scattering-type particle diameter distribution analyzer. As a laser diffraction/scattering type particle diameter distribution analyzer, for example, LA-950V2 manufactured by Horiba, Ltd. is used.

From the viewpoint of step followability, the specific particles preferably have an elastic modulus of 10 MPa or less, more preferably 5 MPa or less, and still more preferably 1 MPa or less at 160° C. The lower limit value of the elastic modulus is not particularly limited, but is preferably 0.2 MPa and more preferably 0.4 MPa from the viewpoint of heat resistance. Specifically, the specific particles preferably have an elastic modulus at 160° C. of 0.2 MPa to 10 MPa and more preferably 0.4 MPa to 5 MPa.

The elastic modulus at 160° C. is measured as an indentation elastic modulus using a nanoindentation method. The indentation elastic modulus is measured by using a microhardness meter (product name “DUH-W201”, manufactured by Shimadzu Corporation) to apply a load at a loading rate of 0.28 mN/sec with a Vickers indenter at 160° C., holding a maximum load of 10 mN for 10 seconds, and then unloading at a loading rate of 0.28 mN/sec.

The specific particles may be organic particles or inorganic particles. In addition, the specific particles may be composite particles containing an organic substance and an inorganic substance. From the viewpoint of step followability, the specific particles are preferably particles containing an organic substance as a main component. The main component means a component having the highest mass ratio among the components constituting the specific particles.

In particular, from the viewpoint of step followability, the specific particles are preferably organic particles.

In addition, from the viewpoint of step followability, the specific particles preferably contain a thermoplastic elastomer.

The thermoplastic elastomer is not particularly limited, and examples thereof include an elastomer including a structural repeating unit derived from styrene (polystyrene-based elastomer), a polyester-based elastomer, a polyolefin-based elastomer, a polyurethane-based elastomer, a polyamide-based elastomer, a polyacryl-based elastomer, a silicone-based elastomer, and a polyimide-based elastomer. The thermoplastic elastomer may be a hydride.

Examples of the polystyrene-based elastomer include a styrene-butadiene-styrene block copolymer (SBS), a styrene-isoprene-styrene block copolymer (SIS), a polystyrene-poly(ethylene-propylene) diblock copolymer (SEP), a polystyrene-poly(ethylene-propylene)-polystyrene triblock copolymer (SEPS), a styrene-ethylene-butylene-styrene block copolymer (SEBS), a polystyrene-poly(ethylene/ethylene-propylene)-polystyrene triblock copolymer (SEEPS), a styrene-isobutylene-styrene block copolymer (SIBS), and hydrides thereof.

Among these, from the viewpoint of dielectric loss tangent and step followability of the polymer film, the layer B preferably contains a thermoplastic resin containing a structural unit derived from a monomer having an aromatic hydrocarbon group, more preferably contains a polystyrene-based elastomer, and more preferably contains a styrene-ethylene-butylene-styrene block copolymer, a styrene-isobutylene-styrene block copolymer, a styrene-ethylene-propylene block copolymer, a styrene-ethylene-propylene-styrene block copolymer, or a styrene-ethylene-ethylene-propylene-styrene copolymer.

From the viewpoint of step followability and heat resistance, the content of the specific particles is preferably 40% by mass or more and less than 100% by mass, and more preferably 60% by mass to 85% by mass with respect to the total amount of the polymer composition.

### (Polymer Having Dielectric Loss Tangent of 0.01 or Less)

The polymer composition according to the present disclosure contains a polymer having a dielectric loss tangent of 0.01 or less.

The dielectric loss tangent of the polymer having a dielectric loss tangent of 0.01 or less is preferably 0.005 or less, and more preferably more than 0 and 0.003 or less.

In the present disclosure, the dielectric loss tangent is measured by the following method.

The dielectric loss tangent is measured by a resonance perturbation method at a frequency of 10 GHz. A 10 GHz cavity resonator (“CP531” manufactured by Kanto Electronic Application & Development Inc.) is connected to a network analyzer (“E8363B” manufactured by Agilent Technologies, Inc.), a measurement sample is inserted into the cavity resonator, and the measurement is performed from the change in resonance frequency before and after the insertion for 96 hours in an environment of a temperature of 25° C. and a humidity of 60% RH.

From the viewpoint of laser processing suitability, the polymer having a dielectric loss tangent of 0.01 or less preferably has a mass residual rate at 440° C. of 80% or more, and more preferably has a mass residual rate at 440° C. of 85% or more. The upper limit value of the mass residual rate at 440° C. is, for example, 100%.

In the present disclosure, the mass residual rate at 440° C. is measured by the following method. 5 mg of a measurement sample is added to a platinum pan, and the measurement is performed at a measurement temperature of 25° C. to 900° C. and a temperature rising rate of 10° C./min using a differential thermal balance (TG-DTA) (TG-8120 manufactured by Rigaku Holdings Corporation), and a value obtained by subtracting the mass (%) at 900° C. from the mass (%) at 440° C. is defined as the mass residual rate.

Examples of the polymer having a dielectric loss tangent of 0.01 or less include thermoplastic resins such as a liquid crystal polymer, a fluororesin, a polymerized substance of a compound which has a cyclic aliphatic hydrocarbon group and a group having an ethylenically unsaturated bond, polyether ether ketone, polyolefin, polyamide, polyester, polyphenylene sulfide, polyether ketone, polycarbonate, polyethersulfone, polyphenylene ether and a modified product thereof, and polyetherimide; elastomers such as a copolymer of glycidyl methacrylate and polyethylene; and thermosetting resins such as a phenol resin, an epoxy resin, a polyimide, and a cyanate resin.

### —Liquid Crystal Polymer—

From the viewpoint of dielectric loss tangent, the polymer having a dielectric loss tangent of 0.01 or less is preferably a liquid crystal polymer. That is, the polymer composition preferably contains a liquid crystal polymer.

The kind of the liquid crystal polymer is not particularly limited, and a known liquid crystal polymer can be used.

In addition, the liquid crystal polymer may be a thermotropic liquid crystal polymer which exhibits liquid crystallinity in a molten state, or may be a lyotropic liquid crystal polymer which exhibits liquid crystallinity in a solution state. In addition, in a case of the thermotropic liquid crystal, it is preferable that the liquid crystal is melted at a temperature of 450° C. or lower.

Examples of the liquid crystal polymer include a liquid crystal polyester, a liquid crystal polyester amide in which an amide bond is introduced into the liquid crystal polyester, a liquid crystal polyester ether in which an ether bond is introduced into the liquid crystal polyester, and a liquid crystal polyester carbonate in which a carbonate bond is introduced into the liquid crystal polyester.

In addition, as the liquid crystal polymer, from the viewpoint of liquid crystallinity, a polymer having an aromatic ring is preferable, and an aromatic polyester or an aromatic polyester amide is more preferable.

Furthermore, the liquid crystal polymer may be a polymer in which an imide bond, a carbodiimide bond, a bond derived from an isocyanate, such as an isocyanurate bond, or the like is further introduced into the aromatic polyester or the aromatic polyester amide.

In addition, it is preferable that the liquid crystal polymer is a fully aromatic liquid crystal polymer formed of only an aromatic compound as a raw material monomer.

Examples of the liquid crystal polymer include the following liquid crystal polymers.
1) a liquid crystal polymer obtained by polycondensing (i) an aromatic hydroxycarboxylic acid, (ii) an aromatic dicarboxylic acid, and (iii) at least one compound selected from the group consisting of an aromatic diol, an aromatic hydroxyamine, and an aromatic diamine.
2) a liquid crystal polymer obtained by polycondensing a plurality of kinds of aromatic hydroxycarboxylic acids.
3) a liquid crystal polymer obtained by polycondensing (i) an aromatic dicarboxylic acid and (ii) at least one compound selected from the group consisting of an aromatic diol, an aromatic hydroxyamine, and an aromatic diamine.
4) a liquid crystal polymer obtained by polycondensing (i) polyester such as polyethylene terephthalate and (ii) an aromatic hydroxycarboxylic acid.

Here, the aromatic hydroxycarboxylic acid, the aromatic dicarboxylic acid, the aromatic diol, the aromatic hydroxyamine, and the aromatic diamine may be each independently replaced with a polycondensable derivative.

A melting point of the liquid crystal polymer is preferably equal to or higher than 250° C., more preferably 250° C. to 350° C., and still more preferably 260° C. to 330° C.

In the present disclosure, the melting point is measured using a differential scanning calorimetry apparatus. For example, the measurement is performed using product name “DSC-60A Plus” (manufactured by Shimadzu Corporation). A temperature rising rate in the measurement is set to 10° C./minute.

The weight-average molecular weight of the liquid crystal polymer is preferably equal to or less than 1,000,000, more preferably 3,000 to 300,000, still more preferably 5,000 to 100,000, and particularly preferably 5,000 to 30,000.

The liquid crystal polymer preferably contains an aromatic polyester amide from a viewpoint of further decreasing the dielectric loss tangent. The aromatic polyester amide is a resin having at least one aromatic ring and having an ester bond and an amide bond. Among these, from the viewpoint of heat resistance, the aromatic polyester amide is preferably a fully aromatic polyester amide.

The aromatic polyester amide is preferably a crystalline polymer. The polymer composition preferably contains a crystalline aromatic polyester amide. In a case where the aromatic polyester amide is crystalline, the dielectric loss tangent is further reduced.

The crystalline polymer refers to a polymer having a clear endothermic peak, not a stepwise endothermic amount changed, in differential scanning calorimetry (DSC). Specifically, for example, this means that a half-width of an endothermic peak in measuring at a temperature rising rate 10° C./minute is within 10° C. A polymer in which a half-width exceeds 10° C. and a polymer in which a clear endothermic peak is not recognized are distinguished as an amorphous polymer from a crystalline polymer.

Aromatic polyester amide preferably contains a structural unit represented by Formula 1, a structural unit represented by Formula 2, and a structural unit represented by Formula 3.

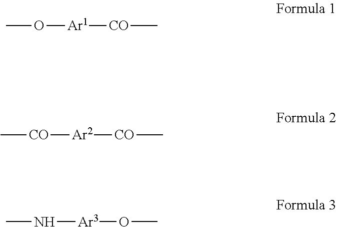

In Formula 1 to Formula 3, Ar¹, Ar², and Ar³ each independently represent a phenylene group, a naphthylene group, or a biphenylylene group.

Hereinafter, the structural unit represented by Formula 1 and the like are also referred to as “unit 1” and the like.

The unit 1 can be introduced, for example, using aromatic hydroxycarboxylic acid as a raw material.

The unit 2 can be introduced, for example, using aromatic dicarboxylic acid as a raw material.

The unit 3 can be introduced, for example, using aromatic hydroxylamine as a raw material.

Here, the aromatic hydroxycarboxylic acid, the aromatic dicarboxylic acid, the aromatic diol, and the aromatic hydroxylamine may be each independently replaced with a polycondensable derivative.

For example, the aromatic hydroxycarboxylic acid and the aromatic dicarboxylic acid can be replaced with aromatic hydroxycarboxylic acid ester and aromatic dicarboxylic acid ester, by converting a carboxy group into an alkoxycarbonyl group or an aryloxycarbonyl group.

The aromatic hydroxycarboxylic acid and the aromatic dicarboxylic acid can be replaced with aromatic hydroxycarboxylic acid halide and aromatic dicarboxylic acid halide, by converting a carboxy group into a haloformyl group.

The aromatic hydroxycarboxylic acid and the aromatic dicarboxylic acid can be replaced with aromatic hydroxycarboxylic acid anhydride and aromatic dicarboxylic acid anhydride, by converting a carboxy group into an acyloxycarbonyl group.

Examples of a polymerizable derivative of a compound having a hydroxy group, such as an aromatic hydroxycarboxylic acid and an aromatic hydroxyamine, include a derivative (acylated product) obtained by acylating a hydroxy group and converting the acylated group into an acyloxy group.

For example, the aromatic hydroxycarboxylic acid and the aromatic hydroxylamine can be each replaced with an acylated product by acylating a hydroxy group and converting the acylated group into an acyloxy group.

Examples of a polycondensable derivative of the aromatic hydroxylamine include a substance (acylated product) obtained by acylating an amino group to convert the amino group into an acylamino group.

For example, the aromatic hydroxyamine can be replaced with an acylated product by acylating an amino group and converting the acylated group into an acylamino group.

In Formula 1, Ar¹ is preferably a p-phenylene group, a 2,6-naphthylene group, or a 4,4′-biphenylylene group, and more preferably a 2,6-naphthylene group.

In a case where Ar¹ is a p-phenylene group, the unit 1 is, for example, a structural unit derived from p-hydroxybenzoic acid.

In a case where Ar¹ is a 2,6-naphthylene group, the unit 1 is, for example, a structural unit derived from 6-hydroxy-2-naphthoic acid.

In a case where Ar¹ is a 4,4′-biphenylylene group, the unit 1 is, for example, a structural unit derived from 4′-hydroxy-4-biphenylcarboxylic acid.

In Formula 2, Ar² is preferably a p-phenylene group, an m-phenylene group, or a 2,6-naphthylene group, and more preferably an m-phenylene group.

In a case where Ar² is a p-phenylene group, the unit 2 is, for example, a structural unit derived from terephthalic acid.

In a case where Ar² is an m-phenylene group, the unit 2 is, for example, a structural unit derived from isophthalic acid.

In a case where Ar² is a 2,6-naphthylene group, the unit 2 is, for example, a structural unit derived from 2,6-naphthalenedicarboxylic acid.

In Formula 3, Ar³ is preferably a p-phenylene group or a 4,4′-biphenylylene group, and more preferably a p-phenylene group.

In a case where Ar³ is a p-phenylene group, the unit 3 is, for example, a structural unit derived from p-aminophenol.

In a case where Ar³ is a 4,4′-biphenylylene group, the unit 3 is, for example, a structural unit derived from 4-amino-4′-hydroxybiphenyl.

With respect to the total content of the unit 1, the unit 2, and the unit 3, a content of the unit 1 is preferably 30 mol % or more, a content of the unit 2 is preferably 35% or less, and a content of the unit 3 is preferably 35 mol % or less.

The content of the unit 1 is preferably 30 mol % to 80 mol %, more preferably 30 mol % to 60 mol %, and particularly preferably 30 mol % to 40 mol % with respect to the total content of the unit 1, the unit 2, and the unit 3.

The content of the unit 2 is preferably 10 mol % to 35 mol %, more preferably 20 mol % to 35 mol %, and particularly preferably 30 mol % to 35 mol % with respect to the total content of the unit 1, the unit 2, and the unit 3.

The content of the unit 3 is preferably 10 mol % to 35 mol %, more preferably 20 mol % to 35 mol %, and particularly preferably 30 mol % to 35 mol % with respect to the total content of the unit 1, the unit 2, and the unit 3.

The total content of the structural units is a value obtained by totaling a substance amount (mol) of each structural unit. The substance amount of each structural unit is calculated by dividing a mass of each structural unit constituting aromatic polyester amide by a formula weight of each structural unit.

In a case where a ratio of the content of the unit 2 to the content of the unit 3 is expressed as [Content of unit 2]/[Content of unit 3](mol/mol), the ratio is preferably 0.9/1 to 1/0.9, more preferably 0.95/1 to 1/0.95, and still more preferably 0.98/1 to 1/0.98.

Aromatic polyester amide may have two kinds or more of the unit 1 to the unit 3 each independently. Alternatively, aromatic polyester amide may have other structural units other than the unit 1 to the unit 3. A content of other structural units is preferably 10% by mole or less and more preferably 5% by mole or less with respect to the total content of all structural units.

Aromatic polyester amide is preferably produced by subjecting a source monomer corresponding to the structural unit constituting the aromatic polyester amide to melt polymerization.

The weight-average molecular weight of aromatic polyester amide is preferably equal to or less than 1,000,000, more preferably 3,000 to 300,000, still more preferably 5,000 to 100,000, and particularly preferably 5,000 to 30,000.

### —Fluororesin—

From the viewpoint of heat resistance and mechanical strength, the polymer having a dielectric loss tangent of 0.01 or less may be a fluororesin.

In the present disclosure, the kind of the fluororesin is not particularly limited, and a known fluororesin can be used.

Examples of the fluororesin include a homopolymer and a copolymer containing a structural unit derived from a fluorinated α-olefin monomer, that is, an α-olefin monomer containing at least one fluorine atom. In addition, examples of the fluororesin include a copolymer containing a structural unit derived from a fluorinated α-olefin monomer, and a structural unit derived from a non-fluorinated ethylenically unsaturated monomer reactive to the fluorinated α-olefin monomer.

Examples of the fluorinated α-olefin monomer include CF₂═CF₂, CHF═CF₂, CH₂═CF₂, CHCl═CHF, CClF═CF₂, CCl₂═CF₂, CClF═CClF, CHF═CCl₂, CH₂═CClF, CCl₂═CClF, CF₃CF═CF₂, CF₃CF═CHF, CF₃CH═CF₂, CF₃CH═CH₂, CHF₂CH═CHF, and perfluoro(alkyl having 2 to 8 carbon atoms) vinyl ether (for example, perfluoromethyl vinyl ether, perfluoropropyl vinyl ether, and perfluorooctyl vinyl ether). Among these, as the fluorinated α-olefin monomer, at least one monomer selected from the group consisting of tetrafluoroethylene (CF₂═CF₂), chlorotrifluoroethylene (CClF═CF₂), (perfluorobutyl)ethylene, vinylidene fluoride (CH₂═CF₂), and hexafluoropropylene (CF₂═CFCF₃) is preferable.

Examples of the non-fluorinated ethylenically unsaturated monomer include ethylene, propylene, butene, and an ethylenically unsaturated aromatic monomer (for example, styrene and α-methylstyrene).

The fluorinated α-olefin monomer may be used alone or in combination of two or more thereof.

In addition, the non-fluorinated ethylenically unsaturated monomer may be used alone or in combination of two or more thereof.

Examples of the fluororesin include polychlorotrifluoroethylene (PCTFE), poly(chlorotrifluoroethylene-propylene), poly(ethylene-tetrafluoroethylene) (ETFE), poly(ethylene-chlorotrifluoroethylene) (ECTFE), poly(hexafluoropropylene), poly(tetrafluoroethylene) (PTFE), poly(tetrafluoroethylene-ethylene-propylene), poly(tetrafluoroethylene-hexafluoropropylene) (FEP), poly(tetrafluoroethylene-propylene) (FEPM), poly(tetrafluoroethylene-perfluoropropylene vinyl ether), poly(tetrafluoroethylene-perfluoroalkyl vinyl ether) (PFA) (for example, poly(tetrafluoroethylene-perfluoropropyl vinyl ether)), polyvinyl fluoride (PVF), polyvinylidene fluoride (PVDF), poly(vinylidene fluoride-chlorotrifluoroethylene), perfluoropolyether, perfluorosulfonic acid, and perfluoropolyoxetane.

The fluororesin may have a structural unit derived from fluorinated ethylene or fluorinated propylene.

The fluororesin may be used alone or in combination of two or more thereof.

The fluororesin is preferably FEP, PFA, ETFE, or PTFE.

The FEP is available from Du Pont as the trade name of TEFLON (registered trademark) FEP or from DAIKIN INDUSTRIES, LTD. as the trade name of NEOFLON FEP. The PFA is available from DAIKIN INDUSTRIES, LTD. as the trade name of NEOFLON PFA, from Du Pont as the trade name of TEFLON (registered trademark) PFA, or from Solvay Solexis as the trade name of HYFLON PFA.

The fluororesin more preferably includes PTFE. The PTFE may be a PTFE homopolymer, a partially modified PTFE homopolymer, or a combination including one or both of these. The partially modified PTFE homopolymer preferably contains a structural unit derived from a comonomer other than tetrafluoroethylene in an amount of less than 1% by mass based on the total mass of the polymer.

The fluororesin may be a crosslinkable fluoropolymer having a crosslinkable group. The crosslinkable fluoropolymer can be crosslinked by a known crosslinking method in the related art. One of the representative crosslinkable fluoropolymers is a fluoropolymer having (meth)acryloyloxy. For example, the crosslinkable fluoropolymer can be represented by the following formula.

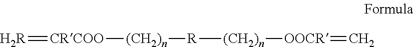

In the formula, R is an oligomer chain having a structural unit derived from the fluorinated α-olefin monomer, R′ is H or —CH₃, and n is 1 to 4. R may be a fluorine-based oligomer chain having a structural unit derived from tetrafluoroethylene.

In order to initiate a radical crosslinking reaction through the (meth)acryloyloxy group in the fluororesin, by exposing the fluoropolymer having a (meth)acryloyloxy group to a free radical source, a crosslinked fluoropolymer network can be formed. The free radical source is not particularly limited, and suitable examples thereof include a photoradical polymerization initiator and an organic peroxide. Appropriate photoradical polymerization initiators and organic peroxides are well known in the art. The crosslinkable fluoropolymer is commercially available, and examples thereof include Viton B manufactured by Du Pont.

—Polymerized Substance of Compound which has Cyclic Aliphatic Hydrocarbon Group and Group Having Ethylenically Unsaturated Bond—

The polymer having a dielectric loss tangent of 0.01 or less may be a polymerized substance of a compound which has a cyclic aliphatic hydrocarbon group and a group having an ethylenically unsaturated bond.

Examples of the polymerized substance of a compound which has a cyclic aliphatic hydrocarbon group and a group having an ethylenically unsaturated bond include thermoplastic resins having a structural unit derived from a cyclic olefin monomer such as norbornene and a polycyclic norbornene-based monomer.

The polymerized substance of a compound which has a cyclic aliphatic hydrocarbon group and a group having an ethylenically unsaturated bond may be a ring-opened polymer of the above-described cyclic olefin, a hydrogenated product of a ring-opened copolymer using two or more cyclic olefins, or an addition polymer of a cyclic olefin and a linear olefin or aromatic compound having an ethylenically unsaturated bond such as a vinyl group. In addition, a polar group may be introduced into the polymerized substance of a compound which has a cyclic aliphatic hydrocarbon group and a group having an ethylenically unsaturated bond.

The polymerized substance of a compound which has a cyclic aliphatic hydrocarbon group and a group having an ethylenically unsaturated bond may be used alone or in combination of two or more thereof.

A ring structure of the cyclic aliphatic hydrocarbon group may be a single ring, a fused ring in which two or more rings are fused, or a crosslinked ring.

Examples of the ring structure of the cyclic aliphatic hydrocarbon group include a cyclopentane ring, a cyclohexane ring, a cyclooctane ring, an isophorone ring, a norbornane ring, and a dicyclopentane ring.

The compound which has a cyclic aliphatic hydrocarbon group and a group having an ethylenically unsaturated bond is not particularly limited, and examples thereof include a (meth)acrylate compound having a cyclic aliphatic hydrocarbon group, a (meth)acrylamide compound having a cyclic aliphatic hydrocarbon group, and a vinyl compound having a cyclic aliphatic hydrocarbon group. Among these, preferred examples thereof include a (meth)acrylate compound having a cyclic aliphatic hydrocarbon group. In addition, the compound which has a cyclic aliphatic hydrocarbon group and a group having an ethylenically unsaturated bond may be a monofunctional ethylenically unsaturated compound or a polyfunctional ethylenically unsaturated compound.

The number of cyclic aliphatic hydrocarbon groups in the compound which has a cyclic aliphatic hydrocarbon group and a group having an ethylenically unsaturated bond may be 1 or more, and may be 2 or more.

It is sufficient that the polymerized substance of a compound which has a cyclic aliphatic hydrocarbon group and a group having an ethylenically unsaturated bond is a polymer obtained by polymerizing at least one compound which has a cyclic aliphatic hydrocarbon group and a group having an ethylenically unsaturated bond, and it may be a polymerized substance of two or more kinds of the compound which has a cyclic aliphatic hydrocarbon group and a group having an ethylenically unsaturated bond or a copolymer with other ethylenically unsaturated compounds having no cyclic aliphatic hydrocarbon group.

In addition, the polymerized substance of a compound which has a cyclic aliphatic hydrocarbon group and a group having an ethylenically unsaturated bond is preferably a cycloolefin polymer.

—Polyphenylene ether—

The polymer having a dielectric loss tangent of 0.01 or less may be a polyphenylene ether.

In the polyphenylene ether, from the viewpoint of dielectric loss tangent and heat resistance, the average number of molecular terminal phenolic hydroxyl groups per molecule (the number of terminal hydroxyl groups) is preferably 1 to 5 and more preferably 1.5 to 3.

The number of terminal hydroxyl groups in the polyphenylene ether can be found, for example, from a standard value of a product of the polyphenylene ether. In addition, the number of terminal hydroxyl groups is expressed as, for example, an average value of the number of phenolic hydroxyl groups per molecule of all polyphenylene ethers present in 1 mol of the polyphenylene ether.

The polyphenylene ether may be used alone or in combination of two or more thereof.

Examples of the polyphenylene ether include a polyphenylene ether consisting of 2,6-dimethylphenol and at least one of bifunctional phenol or trifunctional phenol, and poly(2,6-dimethyl-1,4-phenylene oxide). More specifically, the polyphenylene ether is preferably a compound having a structure represented by Formula (PPE).

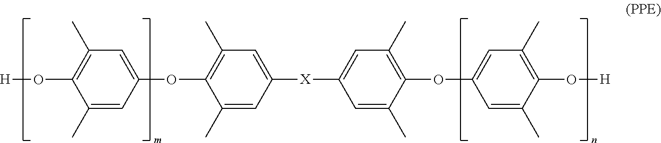

In Formula (PPE), X represents an alkylene group having 1 to 3 carbon atoms or a single bond, m represents an integer of 0 to 20, n represents an integer of 0 to 20, and the sum of m and n represents an integer of 1 to 30.

Examples of the alkylene group in X described above include a dimethylmethylene group.

In a case where heat curing is performed after film formation, from the viewpoint of heat resistance and film-forming property, a weight-average molecular weight (Mw) of the polyphenylene ether is preferably 500 to 5,000 and more preferably 500 to 3,000. In addition, in a case where the heat curing is not performed, the weight-average molecular weight (Mw) of the polyphenylene ether is not particularly limited, but is preferably 3,000 to 100,000 and preferably 5,000 to 50,000.

—Aromatic polyether ketone—

The polymer having a dielectric loss tangent of 0.01 or less may be an aromatic polyether ketone.

The aromatic polyether ketone is not particularly limited, and a known aromatic polyether ketone can be used.

The aromatic polyether ketone is preferably a polyether ether ketone.

The polyether ether ketone is one kind of the aromatic polyether ketone, and is a polymer in which bonds are arranged in the order of an ether bond, an ether bond, and a carbonyl bond. It is preferable that the bonds are linked to each other by a divalent aromatic group.

The aromatic polyether ketone may be used alone or in combination of two or more thereof.

Examples of the aromatic polyether ketone include polyether ether ketone (PEEK) having a chemical structure represented by Formula (P1), polyether ketone (PEK) having a chemical structure represented by Formula (P2), polyether ketone ketone (PEKK) having a chemical structure represented by Formula (P3), polyether ether ketone ketone (PEEKK) having a chemical structure represented by Formula (P4), and polyether ketone ether ketone ketone (PEKEKK) having a chemical structure represented by Formula (P5).

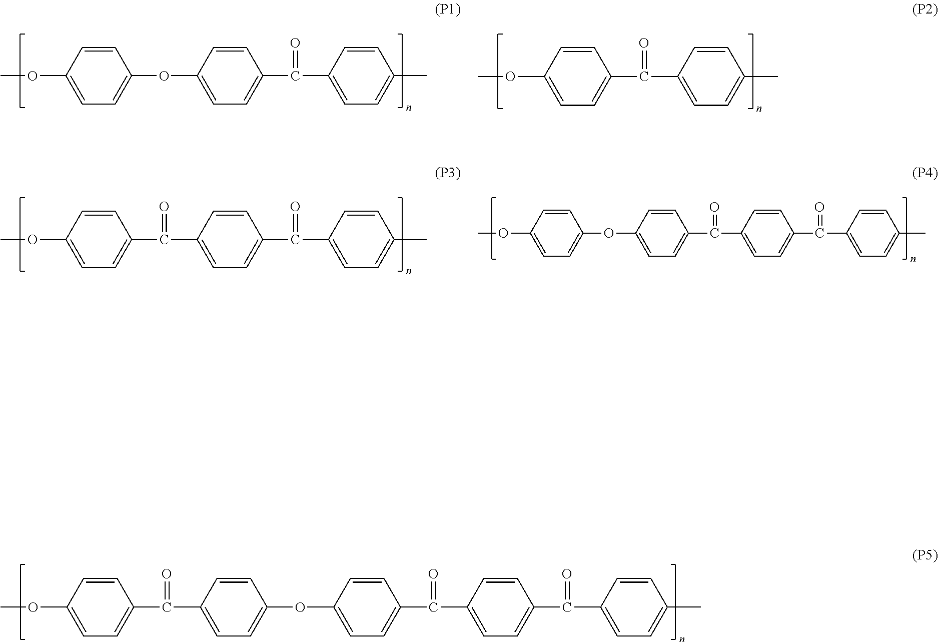

From the viewpoint of mechanical properties, each n of Formulae (P1) to (P5) is preferably 10 or more and more preferably 20 or more. On the other hand, from the viewpoint that the aromatic polyether ketone can be easily produced, n is preferably 5,000 or less and more preferably 1,000 or less. That is, n is preferably 10 to 5,000 and more preferably 20 to 1,000.

The content of the polymer having a dielectric loss tangent of 0.01 or less is preferably 0.1% by mass to 90% by mass, more preferably 1% by mass to 40% by mass, and still more preferably 3% by mass to 20% by mass with respect to the total mass of the polymer composition.

The content of the polymer having a dielectric loss tangent of 0.01 or less is preferably 1% by mass to 100% by mass, more preferably 5% by mass to 50% by mass, and still more preferably 10% by mass to 30% by mass with respect to the total solid content of the polymer composition.

The polymer composition according to the present disclosure may contain other additives in addition to the specific particles and the polymer having a dielectric loss tangent of 0.01.

Known additives can be used as other additives. Examples of other additives include a curing agent, a leveling agent, an antifoaming agent, an antioxidant, an ultraviolet absorber, a flame retardant, and a colorant.

### [Polymer Film Precursor]

The polymer film precursor according to the present disclosure includes particles (specific particles) having a ratio of an average particle diameter D90 to an average particle diameter D50 of 2.3 or less, and a polymer having a dielectric loss tangent of 0.01 or less.

In a case where the particle size distribution of the particles contained in the polymer film precursor is narrow, the distribution width of the elastic modulus in the polymer film is small. In particular, in a case of performing the laminated press working, it is possible to suppress a local decrease in the surface pressure, and the step followability is excellent.

The preferred aspects of the specific particles and the polymer having a dielectric loss tangent of 0.01 or less, which are contained in the polymer film precursor according to the present disclosure, are the same as the preferred aspects of the specific particles and the polymer having a dielectric loss tangent of 0.01 or less, which are contained in the polymer composition according to the present disclosure.

The polymer film precursor according to the present disclosure may contain other additives in addition to the specific particles and the polymer having a dielectric loss tangent of 0.01 or less.

Examples of the other additives include the same additives as those which may be included in the polymer composition according to the present disclosure.

The average thickness of the polymer film precursor according to the present disclosure is not particularly limited, but from the viewpoint of dielectric loss tangent and step followability, is preferably 5 μm to 90 μm, more preferably 10 μm to 70 μm, and particularly preferably 15 μm to 50 μm.

The average thickness of the polymer film precursor is measured at optional five sites using an adhesive film thickness meter, for example, an electronic micrometer (product name “KG3001A”, manufactured by Anritsu Corporation), and the average value of the measured values is defined as the average thickness of the polymer film.

### [Polymer Film]

The polymer film according to the present disclosure has a phase-separated structure including at least two phases, in which a distribution width of an elastic modulus at 160° C. is less than 100 MPa.

In the present disclosure, the “phase-separated structure” means a structure in which at least two portions containing components different from each other are present in the polymer film.

Examples of the phase-separated structure include a sea-island structure, a co-continuous structure, a cylinder structure, and a lamella structure. Among these, the phase-separated structure in the polymer film according to the present disclosure is preferably a sea-island structure. The sea-island structure means a structure in which one phase of the at least two phases forms a continuous phase and the other phase is dispersed in a discontinuous manner.

The fact that the polymer film has a phase-separated structure can be confirmed by using a method of the morphological observation, the method of the material distribution evaluation, method of the mechanical property distribution evaluation, and the like for the surface of the polymer film, the cross section of the polymer film, or both the surface and the cross section of the polymer film. In the present disclosure, in a case where the phase-separated structure can be confirmed by any one of the method of the morphological observation, the method of the material distribution evaluation, or the method of the mechanical property distribution evaluation, it is determined that the film has a phase-separated structure.

The morphological observation is performed using a known optical microscope. In a case where the morphological observation cannot be performed using a known optical microscope, the morphological observation is performed using an electron microscope or the like.

The material distribution evaluation is performed by imaging of an infrared spectroscopy. In a case where the infrared spectroscopy cannot be imaged, imaging of the Raman spectroscopy is used. In a case where the Raman spectroscopy cannot be imaged, imaging of the X-ray photoelectron spectroscopy is used.

The mechanical property distribution evaluation is performed using an atomic force microscope or the like.

The polymer film according to the present disclosure can be produced, for example, by heating the polymer film precursor according to the present disclosure. That is, the polymer film precursor according to the present disclosure is positioned as a precursor of the polymer film according to the present disclosure.

### <First Phase>

It is preferable that the first phase, which is at least one of the two phases, contains a polymer having a dielectric loss tangent of 0.01 or less. The preferred aspect of the polymer having a dielectric loss tangent of 0.01 or less is the same as the preferred aspect of the polymer having a dielectric loss tangent of 0.01 or less, which is contained in the polymer composition according to the present disclosure.

### <Second Phase>

It is preferable that the second phase, which is at least one of the two phases, contains a thermoplastic elastomer. The preferred aspect of the thermoplastic elastomer is the same as the preferred aspect of the thermoplastic elastomer, which may be contained in the polymer composition according to the present disclosure.

In the second phase, it is preferable that at least a part of the thermoplastic elastomer is present in a particle form. Whether or not the second liquid crystal polyester is present in a particle form can be determined by observing a cross section of the polymer film with a scanning electron microscope (SEM).

### <Physical Properties of Polymer Film>

In the polymer film according to the present disclosure, a distribution width of an elastic modulus at 160° C. is less than 100 MPa.

Since the polymer film according to the present disclosure has a distribution width of an elastic modulus at 160° C. of less than 100 MPa, the polymer film has excellent step followability. In the present disclosure, the distribution width of the elastic modulus at 160° C. is measured by the following method.

The storage elastic modulus is determined in a 15 μm square region at 160° C. by observation in a VE-AFM mode using a scanning probe microscope (product name “SPA400”, manufactured by SII Nanotechnology Inc.). The average value of the storage elastic moduli is obtained at each of any five sites in the plane of the polymer film, and the difference between the maximum value and the minimum value is defined as the distribution width of the elastic modulus.

From the viewpoint of further improving the step followability, the distribution width of the elastic modulus at 160° C. is preferably 10 MPa or less, more preferably 3 MPa or less, and still more preferably 1 MPa or less. The lower limit value of the distribution width of the elastic modulus at 160° C. is not particularly limited and may be 0 MPa.

The dielectric loss tangent of the polymer film according to the present disclosure is preferably 0.01 or less, more preferably 0.005 or less, and still more preferably more than 0 and 0.003 or less.

From the viewpoint of laser processing suitability, the polymer film according to the present disclosure preferably has a mass residual rate at 440° C. of 20% or more and more preferably 30% or more. The upper limit value of the mass residual rate at 440° C. is not particularly limited, and is, for example, 100%.

From the viewpoint of heat resistance, the polymer film according to the present disclosure preferably has a viscosity at 260° C. of 1,000 Pa·s or more. The viscosity at 260° C. is 1,000 Pa·s or more, so that the composition has excellent mechanical strength. In particular, in a laminate having a configuration in which a layer having low gas permeability, such as a metal foil, is adjacent, in a case of rapid heating, outgas generated from the inside of the film stays near the surface of the film, the film material flows, and foaming occurs near the surface of the film, thereby causing interlayer peeling. Therefore, in a case where the viscosity of the film at a high temperature is increased, interlayer peeling is less likely to occur in a high temperature environment. That is, the heat resistance is excellent. In addition, in a case where a region where the viscosity is reduced at 260° C. is present, reducing the thickness of the region is also effective in suppressing interlayer peeling.

In the polymer composition of the present disclosure, the ratio of the average particle diameter D90 to the average particle diameter D50 is appropriately controlled, and the formed polymer film has a phase-separated structure that is appropriately controlled. Therefore, the polymer composition is effective for achieving the above-described preferred viscosity and reducing the thickness of the region where the viscosity is reduced.

The viscosity of the polymer film at 260° C. is more preferably 3,000 Pa·s or more. The upper limit value of the viscosity is not particularly limited, but is, for example, 1,000,000 Pa·s.

In the present disclosure, the viscosity of the polymer film at 260° C. is measured by the following method.

A surface of 1 μm of the polymer film is scraped off with a razor, and the surface viscosity at 260° C. is measured using a rheometer equipped with a heating unit (for example, HAAKE MARS, manufactured by Thermo Fisher Scientific Inc.).

The polymer film may have a viscosity of at least one surface of the polymer film at 260° C. of 1,000 Pa·s or more.

The average thickness of the polymer film according to the present disclosure is not particularly limited, but from the viewpoint of dielectric loss tangent and step followability, the average thickness is preferably 5 μm to 90 μm, more preferably 10 μm to 70 μm, and particularly preferably 15 μm to 50 μm.

The average thickness of the polymer film is measured at optional five sites using an adhesive film thickness meter, for example, an electronic micrometer (product name “KG3001A”, manufactured by Anritsu Corporation), and the average value of the measured values is defined as the average thickness of the polymer film.

### [Laminate Precursor]

The laminate precursor according to the present disclosure includes a layer A and a layer B disposed on at least one surface of the layer A, in which the layer B contains particles having a ratio of an average particle diameter D90 to an average particle diameter D50 of 2.3 or less, and a polymer having a dielectric loss tangent of 0.01 or less.

In a case where the particle size distribution of the particles contained in the layer B is narrow, the distribution width of the elastic modulus in the layer B is small. The layer B functions as a step following layer.

### <Layer A>

The laminate precursor according to the present disclosure has a layer A in which a layer B described later is provided. From the viewpoint of setting the dielectric loss tangent of the laminate to 0.01 or less, the layer A preferably contains a polymer having a dielectric loss tangent of 0.01 or less.

The layer A may contain only one kind of polymer having a dielectric loss tangent of 0.01 or less, or may contain two or more kinds thereof. The preferred aspect of the polymer having a dielectric loss tangent of 0.01 or less, which may be contained in the layer A, is the same as the preferred aspect of the polymer having a dielectric loss tangent of 0.01 or less, which is contained in the polymer composition according to the present disclosure.

From the viewpoint of dielectric loss tangent of the laminate, the content of the polymer having a dielectric loss tangent of 0.01 or less is preferably 10% by mass or more, more preferably 20% by mass or more, and particularly preferably 20% by mass to 100% by mass with respect to the total mass of the layer A.

The layer A may contain a filler in addition to the polymer having a dielectric loss tangent of 0.01 or less.

The filler may be in a particle shape, may be in a fibrous shape, may be an inorganic filler, or may be an organic filler.

As the organic filler, a known organic filler can be used.

Examples of a material of the organic filler include polyethylene, polystyrene, urea-formalin filler, polyester, cellulose, acrylic resin, fluororesin, cured epoxy resin, crosslinked benzoguanamine resin, crosslinked acrylic resin, a liquid crystal polymer, and a material containing two or more kinds of these.

In addition, the organic filler may be fibrous, such as nanofibers, or may be hollow resin particles.

Among these, as the organic filler, from the viewpoint of the dielectric loss tangent and the step followability, fluororesin particles, polyester-based resin particles, polyethylene particles, liquid crystal polymer particles, or cellulose-based resin nanofibers are preferable; polytetrafluoroethylene particles, polyethylene particles, or liquid crystal polymer particles are more preferable; and liquid crystal polymer particles are particularly preferable. Here, the liquid crystal polymer particles are not limited, but refer to particles obtained by polymerizing a liquid crystal polymer and pulverizing the liquid crystal polymer with a pulverizer or the like to obtain powdery liquid crystal. The liquid crystal polymer particles are preferably smaller than the thickness of each layer.

The preferred aspect of the liquid crystal polymer constituting the liquid crystal polymer particles is the same as the preferred aspect of the liquid crystal polymer, which may be contained in the polymer composition according to the present disclosure.

From the viewpoint of dielectric loss tangent and step followability, the average particle diameter of the organic filler is preferably 5 nm to 20 μm and more preferably 100 nm to 10 μm.

As the inorganic filler, a known inorganic filler can be used.

Examples of a material of the inorganic filler include BN, Al₂O₃, AlN, TiO₂, SiO₂, barium titanate, strontium titanate, aluminum hydroxide, calcium carbonate, and a material containing two or more of these.

Among these, as the inorganic filler, from the viewpoint of dielectric loss tangent and step followability, metal oxide particles or fibers are preferable, silica particles, titania particles, or glass fibers are more preferable, and silica particles or glass fibers are particularly preferable.

The average particle diameter of the inorganic filler is preferably about 20% to about 40% of the thickness of the film, and for example, a filler having an average particle diameter of 25%, 30%, or 35% of the thickness of the film may be selected. In a case where the particles or fibers are flat, the average particle diameter indicates a length in a short side direction.

In addition, from the viewpoint of dielectric loss tangent and step followability, the average particle diameter of the inorganic filler is preferably 5 nm to 20 μm, more preferably 10 nm to 10 μm, still more preferably 20 nm to 1 μm, and particularly preferably 25 nm to 500 nm.

Among these, from the viewpoint of dielectric loss tangent of the laminate, the filler contained in the layer A is preferably an organic filler and more preferably liquid crystal polymer particles.

The layer A may contain only one or two or more kinds of the fillers.

In a case where the layer A contains a filler, from the viewpoint of dielectric loss tangent and step followability, the content of the filler is preferably 30% by mass to 90% by mass, more preferably 50% by mass to 85% by mass, and still more preferably 60% by mass to 80% by mass with respect to the total mass of the layer A.

The layer A may contain an additive other than the above-described components.

The preferred aspect of the other additives which may be included in the layer A is the same as the preferred aspect of the other additives which may be included in the polymer composition according to the present disclosure.

In addition, the layer A may contain, as other additives, a resin other than the polymer having a dielectric loss tangent of 0.01 or less.

Examples of the resin other than the polymer having a dielectric loss tangent of 0.01 or less include thermoplastic resins other than liquid crystal polyester, such as polypropylene, polyamide, polyester other than liquid crystal polyester, polyphenylene sulfide, polyether ketone, polycarbonate, polyethersulfone, polyphenylene ether and a modified product thereof, and polyetherimide; elastomers such as a copolymer of glycidyl methacrylate and polyethylene; and thermosetting resins such as a phenol resin, an epoxy resin, a polyimide resin, and a cyanate resin.

The total content of the other additives in the layer A is preferably 25 parts by mass or less, more preferably 10 parts by mass or less, and still more preferably 5 parts by mass or less with respect to 100 parts by mass of the content of the polymer having a dielectric loss tangent of 0.01 or less.

The average thickness of the layer A is not particularly limited, but from the viewpoint of dielectric loss tangent of the laminate and step followability, it is preferably 5 μm to 90 m, more preferably 10 μm to 70 μm, and particularly preferably 15 μm to 50 μm.

A measuring method of the average thickness of each layer in the laminate according to the present disclosure is as follows.

The laminate is cut along a plane perpendicular to the plane direction of the laminate, the thickness is measured at five or more points in the cross section, and the average value thereof is defined as the average thickness.

### <Layer B>

The laminate precursor according to the present disclosure includes the layer B on at least one surface of the layer A. The layer B contains the specific particles and a polymer having a dielectric loss tangent of 0.01 or less.

The preferred aspects of the specific particles and the polymer having a dielectric loss tangent of 0.01 or less, which are contained in the laminate precursor according to the present disclosure, are the same as the preferred aspects of the specific particles and the polymer having a dielectric loss tangent of 0.01 or less, which are contained in the polymer composition according to the present disclosure.

The polymer film precursor according to the present disclosure may contain other additives in addition to the specific particles and the polymer having a dielectric loss tangent of 0.01.

Examples of the other additives include the same additives as those which may be included in the polymer composition according to the present disclosure.

From the viewpoint of step followability, the average thickness of the layer B is preferably 5 μm to 50 μm, more preferably 10 μm to 40 μm, and still more preferably 15 μm to μm.

From the viewpoint of adhesiveness with the metal layer, the laminate precursor according to the present disclosure preferably further has a layer C in addition to the above-described layer A and the above-described layer B, and more preferably has the above-described layer B, the above-described layer A, and the above-described layer C in this order.

### <Layer C>

The layer C is preferably an adhesive layer. That is, the layer C is preferably a surface layer (outermost layer).

From the viewpoint of dielectric loss tangent of the laminate, the layer C preferably contains at least one polymer.

The preferred aspect of the polymer used in the layer C is the same as the preferred aspect of the polymer having a dielectric loss tangent of 0.01 or less, which is used in the layer A.

The polymer contained in the layer C may be the same as or different from the polymer contained in the layer A or the layer B, but from the viewpoint of adhesiveness between the layer A and the layer C, it is preferable that the polymer contained in the layer C is the same as the polymer contained in the layer A.

In addition, since the layer C is used to adhere the metal layer and the layer A, it is preferable that the layer C contains an epoxy resin.

The epoxy resin is preferably a crosslinked product of a polyfunctional epoxy compound. The polyfunctional epoxy compound refers to a compound having two or more epoxy groups. The number of epoxy groups in the polyfunctional epoxy compound is preferably 2 to 4.

In particular, from the viewpoint of dielectric loss tangent of the laminate and adhesiveness with the metal layer, the layer C preferably contains aromatic polyester amide and an epoxy resin.

The layer C may contain a filler.

Preferred aspects of the filler which is used in the layer C are the same as the preferred aspects of the filler which is used in the layer A.

The layer C may contain an additive other than the additives described above.

Preferred aspects of other additives which are used in the layer C are the same as the preferred aspects of other additives which are used in the layer A, except as described below.

From the viewpoint of dielectric loss tangent of the laminate and adhesiveness with the metal, it is preferable that the average thickness of the layer C is smaller than the average thickness of the layer A.

From the viewpoint of dielectric loss tangent of the laminate and adhesiveness to the metal layer, a value of T^{A}/T^{C}, which is a ratio of the average thickness T^{A} of the layer A to an average thickness T^{C} of the layer C, is preferably more than 1, more preferably 2 to 100, still more preferably 2.5 to 20, and particularly preferably 3 to 10.

From the viewpoint of dielectric loss tangent of the laminate and adhesiveness to the metal layer, a value of T^{B}/T^{C}, which is a ratio of the average thickness T^{B} of the layer B to the average thickness T^{C} of the layer C, is preferably more than 1, more preferably 2 to 100, still more preferably 2.5 to 20, and particularly preferably 3 to 10.

Furthermore, from the viewpoint of dielectric loss tangent of the laminate and adhesiveness to the metal layer, the average thickness of the layer C is preferably 0.1 μm to 20 μm, more preferably 0.5 μm to 15 μm, still more preferably 1 μm to 10 μm, and particularly preferably 2 μm to 8 μm.

From the viewpoint of strength and electrical characteristics (characteristic impedance) in a case of being laminated with the metal layer, an average thickness of the laminate precursor according to the present disclosure is preferably 6 μm to 200 μm, more preferably 12 μm to 100 μm, and particularly preferably 20 μm to 80 μm.

The average thickness of the laminate precursor is measured at optional five sites using an adhesive film thickness meter, for example, an electronic micrometer (product name, “KG3001A”, manufactured by Anritsu Corporation), and the average value of the measured values is defined as the average thickness of the film.

The dielectric loss tangent of the laminate precursor according to the present disclosure is preferably 0.01 or less, more preferably 0.005 or less, and still more preferably more than 0 and 0.003 or less.

### [Laminate]

The laminate according to the present disclosure includes a layer A, and a layer B disposed on at least one surface of the layer A, in which the layer B has a phase-separated structure including at least two phases, and a distribution width of an elastic modulus at 160° C. of less than 100 MPa.

The laminate according to the present disclosure can be produced, for example, by heating the laminate precursor according to the present disclosure. That is, the laminate precursor according to the present disclosure is positioned as a precursor of the laminate according to the present disclosure.

### <Layer A>

A preferred aspect of the layer A in the laminate according to the present disclosure is the same as the preferred aspect of the layer A in the laminate precursor according to the present disclosure.

### <Layer B>

The laminate according to the present disclosure includes the layer B on at least one surface of the layer A. The layer B is preferably a surface layer (outermost layer). The layer B has a phase-separated structure including at least two phases, and has a distribution width of an elastic modulus at 160° C. of less than 100 MPa.

The preferred aspect of the layer B in the laminate according to the present disclosure is the same as the preferred aspect of the polymer film according to the present disclosure.

In the laminate according to the present disclosure, from the viewpoint of laser processing suitability, the mass residual rate at 440° C. is preferably 30% or more and more preferably 50% or more. The upper limit value of the mass residual rate at 440° C. is not particularly limited, and is, for example, 100%.

### <Production Method of Laminate>

### (Film Formation)

The production method of a laminate according to the present disclosure is not particularly limited, and a known method can be referred to.

Suitable examples of the film forming method include a co-casting method, a multilayer coating method, and a co-extrusion method. Among these, the film forming method is preferably a co-casting method.

In a case where the multilayer structure in the laminate is produced by the co-casting method or the multilayer coating method, it is preferable that the co-casting method or the multilayer coating method is performed by using a composition for forming the layer A, a composition for forming the layer B, a composition for forming the layer C, or the like obtained by dissolving or dispersing components of each layer, such as the liquid crystal polymer, in a solvent.

Examples of the solvent include halogenated hydrocarbons such as dichloromethane, chloroform, 1,1-dichloroethane, 1,2-dichloroethane, 1,1,2,2-tetrachloroethane, 1-chlorobutane, chlorobenzene, and o-dichlorobenzene; halogenated phenols such as p-chlorophenol, pentachlorophenol, and pentafluorophenol; ethers such as diethyl ether, tetrahydrofuran, and 1,4-dioxane; ketones such as acetone and cyclohexanone; esters such as ethyl acetate and γ-butyrolactone; carbonates such as ethylene carbonate and propylene carbonate; amines such as triethylamine; nitrogen-containing heterocyclic aromatic compounds such as pyridine; nitriles such as acetonitrile and succinonitrile; amides such as N,N-dimethylformamide, N,N-dimethylacetamide, and N-methylpyrrolidone; urea compounds such as tetramethylurea; nitro compounds such as nitromethane and nitrobenzene; sulfur compounds such as dimethyl sulfoxide and sulfolane; and phosphorus compounds such as hexamethylphosphoramide and tri-n-butyl phosphate. Among these, two or more kinds thereof may be used in combination.

From the viewpoint of low corrosiveness and satisfactory handleability, a solvent containing, as a main component, an aprotic compound, particularly an aprotic compound having no halogen atom is preferable as the solvent, and the proportion of the aprotic compound in the entire solvent is preferably 50% by mass to 100% by mass, more preferably 70% by mass to 100% by mass, and particularly preferably 90% by mass to 100% by mass. In addition, from the viewpoint of easily dissolving the liquid crystal polymer, as the above-described aprotic compound, it is preferable to use an amide such as N,N-dimethylformamide, N,N-dimethylacetamide, tetramethylurea, and N-methylpyrrolidone, or an ester such as γ-butyrolactone; and it is more preferable to use N,N-dimethylformamide, N,N-dimethylacetamide, or N-methylpyrrolidone.

In addition, as the solvent, a solvent containing, as a main component, a compound having a dipole moment of 3 to 5 is preferable since the liquid crystal polymer is easily dissolved, and a proportion of the compound having the dipole moment of the entire solvent of 3 to 5 is preferably 50% by mass to 100% by mass, more preferably 70% by mass to 100% by mass, and particularly preferably 90% by mass to 100% by mass.

It is preferable to use the compound having a dipole moment of 3 to 5 as the above-described aprotic compound.

In addition, as the solvent, from the viewpoint of ease removal, a solvent containing, as a main component, a compound having a boiling point of 220° C. or lower at 1 atm is preferable, and a proportion of the compound having a boiling point of 220° C. or lower at 1 atm in the entire solvent is preferably 50% by mass to 100% by mass, more preferably 70% by mass to 100% by mass, and particularly preferably 90% by mass to 100% by mass.

It is preferable to use the compound having a boiling point of 220° C. or lower at 1 atm as the above-described aprotic compound.

In addition, in a case where the laminate is produced by a production method such as the co-casting method, the multilayer coating method, the co-extrusion method, or the like described above, a support may be used in the production method of the laminate according to the present disclosure.

Examples of the support include a metal drum, a metal band, a glass plate, a resin film, and a metal foil. Among these, the support is preferably a metal drum, a metal band, or a resin film.

Examples of the resin film include a polyimide (PI) film, and examples of commercially available products thereof include U-PILEX S and U-PILEX R (manufactured by Ube Corporation), KAPTON (manufactured by Du Pont-Toray Co., Ltd.), and IF30, IF70, and LV300 (manufactured by SKC Kolon PI, Inc.).

In addition, the support may have a surface treatment layer formed on the surface so that the support can be easily peeled off. Hard chrome plating, a fluororesin, or the like can be used as the surface treatment layer.

The average thickness of the support is not particularly limited, but is preferably 25 μm to 75 μm and more preferably 50 μm to 75 μm.

In addition, a method for removing at least a part of the solvent from a cast or applied film-like composition (a coating film) is not particularly limited, and a known drying method can be used.

### (Stretching)

In the laminate according to the present disclosure, stretching can be combined as appropriate from the viewpoint of controlling molecular alignment and adjusting thermal expansion coefficiency and mechanical properties. The stretching method is not particularly limited, and a known method can be referred to, and the stretching method may be carried out in a solvent-containing state or in a dry film state. The stretching in the solvent-containing state may be carried out by gripping and stretching the laminate, or may be carried out by utilizing self-contraction due to drying without stretching. The stretching is particularly effective for the purpose of improving the breaking elongation and the breaking strength, in a case where brittleness of the film is reduced by addition of an inorganic filler or the like.

### <Applications>

The laminate according to the present disclosure can be used for various uses. Among the various purposes, the polymer film according to the present disclosure can be used suitably for a film for an electronic component such as a printed wiring board and more suitably for a flexible printed circuit board.

In addition, the laminate according to the present disclosure can be suitably used as a liquid crystal polymer film for metal adhesion.

### EXAMPLES

Hereinafter, the present disclosure will be described in more detail with reference to Examples. The materials, the used amounts, the proportions, the treatment contents, the treatment procedures, and the like described in the following examples can be appropriately changed without departing from the gist of the present disclosure. Therefore, the scope of the present disclosure is not limited to the following specific examples.

Details of each material used for preparing the polymer film and the laminate are as follows.

### <Polymer>

P1: Aromatic polyester amide prepared by the following preparation method

### —Synthesis of Aromatic Polyester Amide P1—

940.9 g (5.0 mol) of 6-hydroxy-2-naphthoic acid, 415.3 g (2.5 mol) of isophthalic acid, 377.9 g (2.5 mol) of acetaminophen, 867.8 g (8.4 mol) of acetic anhydride are put in a reactor comprising a stirring device, a torque meter, a nitrogen gas introduction pipe, a thermometer, and a reflux condenser, gas in the reactor is substituted with nitrogen gas, a temperature is raised from a room temperature (23° C., the same applies hereinafter) to 140° C. over 60 minutes while stirring under a nitrogen gas flow, and refluxing is performed at 140° C. for three hours.

Next, the temperature was raised from 150° C. to 300° C. over 5 hours while distilling off by-produced acetic acid and unreacted acetic anhydride, and maintained at 300° C. for 30 minutes. Thereafter, a content is taken out from the reactor and is cooled to the room temperature. The obtained solid was pulverized by a pulverizer to obtain a powdered aromatic polyester amide A1a. A flow start temperature of the aromatic polyester amide P1a was 193° C. In addition, the aromatic polyester amide P1a was a fully aromatic polyester amide.

The aromatic polyester amide P1a was subjected to solid phase polymerization by raising the temperature from room temperature to 160° C. over 2 hours and 20 minutes in a nitrogen atmosphere, increasing the temperature from 160° C. to 180° C. over 3 hours and 20 minutes, and maintaining the temperature at 180° C. for 5 hours, and then the resultant was cooled. Next, the resultant was pulverized by a pulverizer to obtain a powdered aromatic polyester amide A1b. A flow start temperature of the aromatic polyester amide P1b was 220° C.

Aromatic polyester amide P1b is subjected to solid phase polymerization by raising the temperature from the room temperature to 180° C. for one hour and 25 minutes, next increasing the temperature from 180° C. to 255° C. over six hours and 40 minutes, and maintaining the temperature at 255° C. for five hours in a nitrogen atmosphere, and then, is cooled, and powdered aromatic polyester amide P1 is obtained.

A flow start temperature of the aromatic polyester amide P1 was 302° C. A melting point of aromatic polyester amide P1 was measured using a differential scanning calorimetry apparatus, and the result was 311° C. The dielectric loss tangent of the aromatic polyester amide P1 was 0.003. Solubility of aromatic polyester amide P1 with respect to N-methylpyrrolidone at 140° C. is equal to or greater than 1% by mass. The aromatic polyester amide P1 had a mass residual rate at 440° C. of 93%.

### <Particles>

F1: Particles of a styrene-isobutylene-styrene block copolymer (thermoplastic elastomer) prepared according to the following production method, elastic modulus at 160° C.: 1.1 MPa

F2: Particles of a styrene-ethylene-butylene-styrene block copolymer (thermoplastic elastomer) prepared according to the following production method, elastic modulus at 160° C.: 0.16 MPa

F3: Particles of a styrene-ethylene-butylene-styrene block copolymer (thermoplastic elastomer) prepared according to the following production method, elastic modulus at 160° C.: 0.16 MPa

### —Preparation of Dispersion Liquid Containing Particles F1 of Styrene-Isobutylene-Styrene Block Copolymer—

90 g of toluene was added to 10 g of SIBS (product name “SIBSTAR 103T-UL”, manufactured by Kaneka Corporation) and stirred to prepare a toluene solution of SIBS. Subsequently, 0.003 g of a surfactant and 100 g of water were added thereto and stirred to obtain a dispersion liquid containing the particles F1 of SIBS. The obtained dispersion liquid was filtered to obtain a mixture of the particles F1 and the surfactant.

As the surfactant, a polymer consisting of a structural unit A derived from 2,2-difluoroethyl methacrylate and a structural unit B derived from tert-butyl acrylate (structural unit A: structural unit B=60:40 (mass ratio), weight-average molecular weight: 14,000) was used.

### —Preparation of Dispersion Liquid Containing Particles F2 of Styrene-Ethylene-Butylene-Styrene Block Copolymer—

90 g of toluene was added to 10 g of SEBS (product name “TUFTEC M1913”, manufactured by Asahi Kasei Corporation) and stirred to prepare a toluene solution of SEBS. Subsequently, 0.003 g of the above-described surfactant and 100 g of water were added thereto and stirred to obtain a dispersion liquid containing particles F2 of SEBS. The obtained dispersion liquid was filtered to obtain a mixture of the particles F2 and the surfactant.

### —Preparation of Particles F3 of Styrene-Ethylene-Butylene-Styrene Block Copolymer—

SEBS (product name “TUFTEC M1913”, manufactured by Asahi Kasei Corporation) was frozen and pulverized to obtain particles F3 of SEBS.

The average particle diameter D50 and the average particle diameter D90 of the prepared particles F1 to F3 were measured using a laser diffraction/scattering-type particle size distribution analyzer (product name “LA-950V2”, manufactured by Horiba, Ltd.). Table 1 shows the average particle diameter D90 (“D90/D50”) with respect to the average particle diameter D50 and the average particle diameter D90.

### <Filler>

PP-1: Liquid crystal polymer particles prepared by production method described below

### —Synthesis of Liquid Crystal Polymer Particles PP-1—

1034.99 g (5.5 mol) of 2-hydroxy-6-naphthoic acid, 89.18 g (0.41 mol) of 2,6-naphthalenedicarboxylic acid, 236.06 g (1.42 mol) of terephthalic acid, 341.39 g (1.83 mol) of 4,4-dihydroxybiphenyl, and potassium acetate and magnesium acetate as a catalyst were put in a reactor including a stirring device, a torque meter, a nitrogen gas introduction pipe, a thermometer, and a reflux condenser. Gas in the reactor is substituted with nitrogen gas, and then, acetic anhydride (1.08 molar equivalent with respect to a hydroxyl group) is further added. A temperature is raised from a room temperature to 150° C. over 15 minutes while stirring under a nitrogen gas flow, and refluxing is performed at 150° C. for two hours.

Next, the temperature was raised from 150° C. to 310° C. over 5 hours while distilling off by-produced acetic acid and unreacted acetic anhydride, and a polymerized substance was cooled to room temperature. An obtained polymerized substance increases in temperature from the room temperature to 295° C. over 14 hours, and is subjected to solid phase polymerization at 295° C. for one hour. After the solid phase polymerization, the temperature was lowered to room temperature over 5 hours, thereby obtaining liquid crystal polymer particles PP-1. The liquid crystal polymer particles PP-1 had a median diameter (D50) of 7 μm, a dielectric loss tangent of 0.0007, and a melting point of 334° C. The liquid crystal polymer particles PP-1 had a mass residual rate at 440° C. of 93%.

Next, in order to produce a polymer film and a laminate, a solution for forming a layer A, a solution for forming a layer B, and a solution for forming a layer C were prepared. The polymer film was produced using a solution for forming the layer B.

—Preparation of Solution for Forming Layer a—

The polymer and the filler shown in Table 1 were mixed together at the contents (% by mass) shown in Table 1, N-methylpyrrolidone was added thereto, and the concentration of solid contents was adjusted to 25% by mass, thereby obtaining a solution for forming a layer A.

### —Preparation of Solution for Forming Layer B—

The polymers and particles shown in Table 1 were mixed together at the contents (% by mass) shown in Table 1, methyl isobutyl ketone was added thereto, and the concentration of solid contents was adjusted to 20% by mass, thereby obtaining a solution for forming a layer B. In Examples 1 to 9, the particles were mixed in a state of a mixture of the particles and the surfactant.

### —Preparation of Solution for Forming Layer C—

8 parts of aromatic polyester amide P1 was added to 92 parts of N-methylpyrrolidone, and the mixture was stirred at 140° C. for 4 hours in a nitrogen atmosphere to obtain an aromatic polyester amide solution P1 (concentration of solid contents: 8% by mass).

0.04 parts by mass of an aminophenol-type epoxy resin (product name “jER630”, manufactured by Mitsubishi Chemical Corporation) was mixed with the aromatic polyester amide solution P1 (10.0 parts by mass) to prepare a solution for forming a layer C.

In Examples 1 to 6, Examples 8 and 9, and Comparative Example 1, a laminate precursor and a laminate were produced. In Example 7, a polymer film precursor and a polymer film were prepared.

### [Preparation of Laminate Precursor (Single-Sided Copper-Clad Multilayer Film Precursor)]

The obtained solution for forming a layer C and the obtained solution for forming a layer A were fed to a slot die coater equipped with a slide coater, and applied in a two-layer configuration (layer C/layer A) to a treated surface of a copper foil (product name “CF-T9DA-SV-18”, average thickness: 18 μm, manufactured by Fukuda Metal Foil & Powder Co., Ltd.) by adjusting a flow rate so that the film thicknesses shown in Table 1 were obtained. The solvent was removed from the coating film by drying at 40° C. for 4 hours. Further, the temperature was raised from room temperature (25° C.) to 300° C. at 1° C./min in a nitrogen atmosphere. A heat treatment of holding the film at 300° C. for 2 hours was carried out to obtain a polymer film having a copper layer.

The obtained solution for forming a B layer was fed to a slot die coater equipped with a slide coater. The flow rate was adjusted so that the obtained polymer film having a copper layer had a film thickness shown in Table 1, and the B layer forming solution was applied. The solvent was removed from the coating film by drying at 40° C. for 4 hours. A laminate precursor (a single-sided copper-clad multilayer film precursor) having a copper layer, a layer C, a layer A, and a layer B in this order was obtained.

### [Preparation of Polymer Film Precursor (Single-Sided Copper-Clad Single-Layer Film Precursor)]

The obtained solution for forming a layer B was fed to a slot die coater equipped with a slide coater, and applied in a single layer configuration by adjusting the flow rate so that the film thickness was as shown in Table 1 on the treated surface of the copper foil. The coating film was dried at 40° C. for 4 hours to remove the solvent from the coating film, thereby obtaining a single-sided copper-clad single-layer film precursor.

### [Preparation of Laminate (Single-Sided Copper-Clad Multilayer Film)]

The obtained single-sided copper-clad multilayer film precursor was heated from room temperature (25° C.) to 230° C. at 1° C./min in a nitrogen atmosphere. A heat treatment was performed at 230° C. for 2 hours to obtain a single-sided copper-clad multilayer film. The layer B in the obtained single-sided copper-clad multilayer film contained a phase derived from a polymer and a phase derived from particles, and had a sea-island structure (phase-separated structure).

### [Preparation of Polymer Film (Single-Sided Copper-Clad Single-Layer Film)]

The obtained single-sided copper-clad single-layer film precursor was heated from room temperature (25° C.) to 230° C. at 1° C./min in a nitrogen atmosphere. A heat treatment was performed at 230° C. for 2 hours to obtain a single-sided copper-clad single-layer film. The film in the obtained single-sided copper-clad single-layer film contained a phase derived from a polymer and a phase derived from particles, and had a sea-island structure (phase-separated structure).

The viscosity of the layer B of Examples 1 to 6, 8, and Comparative Example 1 at 260° C. was 140,000 Pa·s.

The viscosity of the layer Ain Examples 1 to 6 and 8 at 260° C. was 760,000 Pa·s. The viscosity of the layer A of Comparative Example 1 at 260° C. was 820 Pa·s.

The viscosity of the polymer film of Example 7 at 260° C. was 760,000 Pa·s.

### [Preparation of Wiring Board]

—Preparation of Substrate with Wiring Pattern—

A copper foil (product name “CF-T9DA-SV-18”, average thickness: 18 m, manufactured by Fukuda Metal Foil & Powder Co., Ltd.) and a liquid crystal polymer film (product name “CTQ-50”, average thickness: 50 μm, manufactured by Kuraray Co., Ltd.) as a substrate were produced. The copper foil, the substrate, and the copper foil were laminated in this order such that the treated surface of the copper foil was in contact with the substrate. A double-sided copper foil laminated plate precursor was obtained by performing a laminating treatment for 1 minute under conditions of 140° C. and a laminating pressure of 0.4 MPa using a laminator (product name “Vacuum Laminator V-130”, manufactured by Nikko-Materials Co., Ltd.). Subsequently, using a thermal compression machine (product name “MP-SNL”, manufactured by Toyo Seiki Seisaku-sho, Ltd.), the obtained double-sided copper-clad laminated plate precursor was thermally compression-bonded for 10 minutes under conditions of 300° C. and 4.5 MPa to prepare a double-sided copper-clad laminated plate.

Each of the copper foils on both surfaces of the above-described double-sided copper-clad laminated plate was etched to perform patterning, and a substrate with wiring patterns including a ground line and three pairs of signal lines on both sides of the substrate was prepared. The length of the signal line was set to 100 mm, and three types of line and space (L/S) of 5 μm/5 μm, 20 μm/20 μm, and 50 μm/50 μm were prepared.

### —Preparation Method a of Wiring Board—

In Examples 1 to 6, Examples 8 and 9, and Comparative Example 1, a flexible printed circuit board having a four-layer strip line structure of an outer layer plane (ground layer) was produced using a single-sided copper-clad multilayer film.

Using the above-described substrate with a wiring pattern and the above-described pair of single-sided copper-clad multilayer films, the single-sided copper-clad multilayer film was overlapped on the substrate with a wiring pattern such that the layer B side of the single-sided copper-clad multilayer film was in contact with the wiring pattern of the substrate with a wiring pattern, thereby forming a structure of single-sided copper-clad multilayer film/substrate with a wiring pattern/single-sided copper-clad multilayer film. A wiring board was obtained by performing heat press for 1 hour under conditions of 300° C. and 4 MPa using a vacuum press device.

### —Preparation Method B of Wiring Board—

In Example 7, a flexible wiring board having a four-layer strip line structure of an outer layer plane (ground layer) was prepared using a single-sided copper-clad single-layer film.

Using the above-described substrate with a wiring pattern and the above-described pair of single-sided copper-clad single-layer films, the single-sided copper-clad single-layer film was overlapped on the substrate with a wiring pattern such that the film side of the single-sided copper-clad single-layer film was in contact with the wiring pattern of the substrate with a wiring pattern, thereby forming a structure of single-sided copper-clad single-layer film/wiring pattern with a substrate/single-sided copper-clad single-layer film. A wiring board was obtained by performing heat press for 1 hour under conditions of 300° C. and 4 MPa using a vacuum press device.

### <<Evaluation>>

The prepared single-sided copper-clad single-layer film precursor, single-sided copper-clad single-layer film, single-sided copper-clad multilayer film precursor, and single-sided copper-clad multilayer film were subjected to the following measurement and evaluation, and the results are shown in Table 1.

### <<Measuring Method>>

### [Distribution Width of Elastic Modulus]

The storage elastic modulus was observed in a VE-AFM mode using a scanning probe microscope (product name “SPA400”, manufactured by SII Nanotechnology Inc.) and the average value of the storage elastic modulus in a region of 15 μm square was determined at 160° C.

In Examples 1 to 6 and 8 to 9, the average value of the storage elastic moduli at each of any five sites in the layer B surface of the single-sided copper-clad multilayer film was obtained, and the difference between the maximum value and the minimum value was defined as the distribution width of the elastic modulus.

In Example 7, the average value of the storage elastic moduli at any five sites in the film surface of the single-sided copper-clad single-layer film was obtained, and the difference between the maximum value and the minimum value was defined as the distribution width of the elastic modulus.

### [Mass Residual Rate at 440° C.]

In Examples 1 to 6 and Examples 8 and 9, a measurement sample was collected from the layer B of the single-sided copper-clad multilayer film. In addition, a measurement sample was collected from the film of the single-sided copper-clad multilayer film.

In Example 7, a measurement sample was collected from the film of the single-sided copper-clad single-layer film. 5 mg of a measurement sample was added to a platinum pan, and the measurement was performed at a measurement temperature of 25° C. to 900° C. and a temperature rising rate of 10° C./min using a differential thermal balance (TG-DTA) (TG-8120 manufactured by Rigaku Holdings Corporation), and a value obtained by subtracting the mass (%) at 900° C. from the mass (%) at 440° C. was adopted.

### [Dielectric Loss Tangent]

The dielectric loss tangent was measured using a film obtained by removing the copper foil of the single-sided copper-clad single-layer film and the copper foil of the single-sided copper-clad multilayer film with an aqueous solution of ferric chloride, and drying after washing with pure water.

The dielectric loss tangent was measured by a resonance perturbation method at a frequency of 10 GHz. A 10 GHz cavity resonator (“CP531” manufactured by Kanto Electronic Application & Development Inc.) is connected to a network analyzer (“E8363B” manufactured by Agilent Technologies, Inc.), the measurement sample is inserted into the cavity resonator, and the dielectric loss tangent of the measurement sample is measured from change in resonance frequency before and after insertion for 96 hours in an environment of a temperature of 25° C. and humidity of 60% RH.

### <<Evaluation Method>>

### [Step Followability]

The wiring board was cut with a microtome, the cross section was observed with an optical microscope, and the evaluation was performed based on the following evaluation standards.

A: There is no gap around the wiring pattern of L/S=5 μm/5 μm, and no distortion of the ground line is recognized.

B: There is no gap around the wiring pattern of L/S=20 μm/20 μm, and no distortion of the ground line is recognized.

C: There is no gap around the wiring pattern of L/S=50 μm/50 μm, and no distortion of the ground line was recognized.

D: There is a gap around the wiring pattern of L/S=50 μm/50 μm, or distortion of the ground line is recognized.

### [Laser Processing Suitability]

In Examples 1 to 6, Examples 8 and 9, and Comparative Example 1, a treated surface of a copper foil (product name “CF-T9DA-SV-18”, average thickness: 18 μm, manufactured by Fukuda Metal Foil & Powder Co., Ltd.) was overlapped on the layer B surface side of the prepared single-sided copper-clad multilayer film. A laminating treatment was performed for 1 hour under the conditions of 300° C. and 4 MPa using a laminator (product name “Vacuum laminator V-130”, manufactured by Nikko-Materials Co., Ltd.) to obtain a double-sided copper-clad multilayer film.

Through-hole via processing was performed from the layer C side of the double-sided copper-clad multilayer film using a laser processing machine (UV-YAG laser Model 5330 manufactured by ESI). The via portion was cut with a microtome, and the cross section was observed with an optical microscope, and the length of the peeling of the layer A and the layer B (that is, the maximum length of the recess formed in the cross section of the cut portion in a horizontal direction).

In Example 7, a copper foil (product name “CF-T9DA-SV-18”, average thickness: 18 m, manufactured by Fukuda Metal Foil & Powder Co., Ltd.) was overlapped on the film side of the prepared single-sided copper-clad single-layer film so that the treated surface of the copper foil was in contact with the film side. A laminating treatment was performed for 1 hour under the conditions of 300° C. and 4 MPa using a laminator (product name “Vacuum laminator V-130”, manufactured by Nikko-Materials Co., Ltd.) to obtain a double-sided copper-clad single-layer film.

Through-hole via processing was performed using a laser processing machine (UV-YAG laser Model 5330 manufactured by ESI). The via portion was cut with a microtome, the cross section was observed with an optical microscope, and the length of the burr of the polymer film (that is, the maximum length of the recess formed in the cross section in the horizontal direction at the cut portion) was measured.

### [Evaluation of Heat Resistance-1]

The prepared double-sided copper-clad laminated plate was cut out to a size of 30 mm×30 mm and used as an evaluation sample. The sample was immersed in the hot solder at 288° C. for 10 seconds. The sample after performing the dipping operation three times was cut with a razor, the cross section was observed with an optical microscope, and the peeling state was evaluated based on the following evaluation standards.

A: No peeling was recognized between the layer B and the second metal layer.

B: Peeling was recognized between the layer B and the second metal layer with a width of 1 mm or less.

C: peeling was recognized between the layer B and the second metal layer with a width of more than 1 mm.

### [Evaluation of Heat Resistance-2]

The prepared double-sided copper-clad laminated plate was cut out to a size of 30 mm×30 mm and used as an evaluation sample. The sample was treated in a constant temperature and humidity tank at a temperature of 85° C. and a relative humidity of 85% for 168 hours. Next, the sample was placed in an oven at 260° C. The sample after heating for 15 minutes was cut with a razor, and the cross section was observed with an optical microscope, and the peeling state was evaluated based on the following evaluation standards.

A: No peeling was recognized between the layer B and the second metal layer.

B: Peeling was recognized between B and the second metal layer with a width of 1 mm or less.

C: Peeling was recognized between B and the second metal layer with a width of more than 1 mm.

TABLE 1

| | Layer B of laminate precursor/polymer film precursor | | | | | | | | | | | | |
|---|---|---|---|---|---|---|---|---|---|---|---|---|---|
| | | | | | | | Surfac- | | Layer A of laminate precursor | | | | |
| | Polymer | | Particles | | | | tant | | Polymer | | Filler | | |
| | | Content | | Content | | | Content | Thick- | | Content | | Content | Thick- |
| | | [% by | | [% by | D90/ | D90 | [% by | ness | | [% by | | [% by | ness |
| | Kind | mass] | Kind | mass] | D50 | [μm] | mass] | [μm] | Kind | mass] | Kind | mass] | [μm] |
| Example | P1 | 19.99 | F1 | 79.98 | 1.5 | 6.4 | 0.03 | 25 | P1 | 25 | PP-1 | 75 | 22 |
| 1 | | | | | | | | | | | | | |
| Example | P1 | 19.99 | F1 | 79.98 | 1.4 | 10 | 0.03 | 25 | P1 | 25 | PP-1 | 75 | 22 |
| 2 | | | | | | | | | | | | | |
| Example | PI | 19.99 | F2 | 79.98 | 1.5 | 10 | 0.03 | 25 | P1 | 25 | PP-1 | 75 | 22 |
| 3 | | | | | | | | | | | | | |
| Example | P1 | 19.99 | F1 | 79.98 | 1.3 | 8.7 | 0.03 | 25 | P1 | 25 | PP-1 | 75 | 22 |
| 4 | | | | | | | | | | | | | |
| Example | P1 | 19.99 | F1 | 79.98 | 2.0 | 20 | 0.03 | 25 | P1 | 25 | PP-1 | 75 | 22 |
| 5 | | | | | | | | | | | | | |
| Example | P1 | 19.99 | F1 | 79.98 | 2.0 | 25 | 0.03 | 25 | P1 | 25 | PP-1 | 75 | 22 |
| 6 | | | | | | | | | | | | | |
| Example | P1 | 19.99 | F1 | 79.98 | 1.5 | 6.4 | 0.03 | 25 | — | — | — | — | — |
| 7 | | | | | | | | | | | | | |
| Example | P1 | 59.98 | F2 | 39.99 | 1.5 | 10 | 0.03 | 25 | P1 | 25 | PP-1 | 75 | 22 |
| 8 | | | | | | | | | | | | | |
| Example | P1 | 10 | F2 | 89.97 | 1.5 | 10 | 0.03 | 25 | P1 | 25 | PP-1 | 75 | 22 |
| 9 | | | | | | | | | | | | | |
| Comparative | P1 | 20 | F3 | 80 | 2.6 | 20 | — | 25 | P1 | 25 | PP-1 | 75 | 22 |
| Example | | | | | | | | | | | | | |
| 1 | | | | | | | | | | | | | |

| | Laminate/polymer film | | | | | | | |
|---|---|---|---|---|---|---|---|---|
| | Mass | | | | | | | |
| | residual | Mass | | | Evaluation | | | |
| | rate of | residual | Width of | Dielec- | Step | Laser | | |
| | layer B | rate at | elastic | tric | fol- | processing | Heat resistance | |
| | at 440° C. | 440° C. | modulus | loss | lowabil- | suitability | Evalu- | Evalu- |
| | [%] | [%] | [MPa] | tangent | ity | [μm] | ation-1 | ation-2 |
| Example | 37 | 65 | 0.1 | 0.002 | A | 5 | A | A |
| 1 | | | | | | | | |
| Example | 37 | 65 | 0.2 | 0.002 | A | 5 | A | A |
| 2 | | | | | | | | |
| Example | 37 | 65 | 0.2 | 0.002 | A | 5 | A | B |
| 3 | | | | | | | | |
| Example | 37 | 65 | 0.0 | 0.002 | A | 5 | A | A |
| 4 | | | | | | | | |
| Example | 36 | 64 | 2.0 | 0.002 | B | 8 | A | B |
| 5 | | | | | | | | |
| Example | 35 | 64 | 4.0 | 0.002 | C | 9 | B | B |
| 6 | | | | | | | | |
| Example | — | 37 | 0.1 | 0.002 | A | 4 | A | A |
| 7 | | | | | | | | |
| Example | 66 | 80 | 0.2 | 0.002 | C | 5 | A | A |
| 8 | | | | | | | | |
| Example | 20 | 57 | 0.2 | 0.002 | A | 14 | A | B |
| 9 | | | | | | | | |
| Comparative | 34 | 64 | 16 | 0.002 | D | 17 | C | C |
| Example | | | | | | | | |
| 1 | | | | | | | | |

As shown in Table 1, it was found that, in Examples 1 to 9, since the polymer composition containing the particles having the ratio of the average particle diameter D90 to the average particle diameter D50 of 2.3 or less and the polymer having a dielectric loss tangent of 0.01 or less was used, the step followability was excellent.

On the other hand, in Comparative Example 1, it was found that the particles having the ratio of the average particle diameter D90 to the average particle diameter D50 of 2.3 or less were not included, and the step followability was deteriorated.

In a case where the step followability was evaluated using a substrate with a wiring pattern in which the width of the wiring pattern was set to 100 μm and the wiring board, no gap was recognized around the wiring pattern in any of Examples 1 to 9 and Comparative Example 1.

That is, it was found that, by using a polymer composition containing particles having a ratio of an average particle diameter D90 to an average particle diameter D50 of 2.3 or less and a polymer having a dielectric loss tangent of 0.01 or less, it is possible to follow a finer step (for example, a wiring line) than in the related art.

In addition, it was found that the heat resistance was also excellent in Examples 1 to 9.

The disclosure of Japanese Patent Application No. 2022-201482 filed on Dec. 16, 2022 is incorporated in the present specification by reference. In addition, all documents, patent applications, and technical standards described in the present specification are herein incorporated by reference to the same extent that each individual document, patent application, or technical standard was specifically and individually indicated to be incorporated by reference.

What is claimed is:

1. A polymer composition comprising:
particles having a ratio of an average particle diameter D90 to an average particle diameter D50 of 2.3 or less; and
a polymer having a dielectric loss tangent of 0.01 or less.

2. The polymer composition according to claim 1,
wherein the average particle diameter D90 is 20 μm or less.

3. The polymer composition according to claim 1,
wherein a content of the particles is 40% by mass or more and less than 100% by mass with respect to a total amount of the polymer composition.

4. The polymer composition according to claim 1,
wherein the particles have an elastic modulus at 160° C. of 10 MPa or less.

5. The polymer composition according to claim 1,
wherein the particles contain an organic substance as a main component.

6. The polymer composition according to claim 1,
wherein the particles contain a thermoplastic elastomer.

7. The polymer composition according to claim 1,
wherein the polymer having a dielectric loss tangent of 0.01 or less has a mass residual rate at 440° C. of 80% or more.

8. The polymer composition according to claim 1,
wherein the polymer having a dielectric loss tangent of 0.01 or less contains an aromatic polyester amide.

9. A polymer film precursor comprising:
particles having a ratio of an average particle diameter D90 to an average particle diameter D50 of 2.3 or less; and
a polymer having a dielectric loss tangent of 0.01 or less.

10. The polymer film precursor according to claim 9,
wherein the average particle diameter D90 is 20 μm or less.

11. The polymer film precursor according to claim 9,
wherein a content of the particles is 40% by mass or more and less than 100% by mass with respect to a total amount of the polymer film precursor.

12. The polymer film precursor according to claim 9,
wherein the particles have an elastic modulus at 160° C. of 10 MPa or less.

13. The polymer film precursor according to claim 9,
wherein the particles contain a thermoplastic elastomer.

14. The polymer film precursor according to claim 9,
wherein the polymer having a dielectric loss tangent of 0.01 or less has a mass residual rate at 440° C. of 80% or more.

15. The polymer film precursor according to claim 9,
wherein the polymer having a dielectric loss tangent of 0.01 or less contains an aromatic polyester amide.

16. A polymer film comprising:
a phase-separated structure including at least two phases,
wherein a distribution width of an elastic modulus at 160° C. is less than 100 MPa.

17. The polymer film according to claim 16,
wherein the polymer film has a mass residual rate at 440° C. of 20% or more.

18. The polymer film according to claim 16,
wherein the polymer film has a viscosity at 260° C. of 1,000 Pa·s or more.

19. A laminate precursor comprising:
a layer A; and
a layer B disposed on at least one surface of the layer A,
wherein the layer B contains particles having a ratio of an average particle diameter D90 to an average particle diameter D50 of 2.3 or less, and a polymer having a dielectric loss tangent of 0.01 or less.

20. A laminate comprising
a layer A; and
a layer B disposed on at least one surface of the layer A,
wherein the layer B has a phase-separated structure including at least two phases, and a distribution width of an elastic modulus at 160° C. of less than 100 MPa.
